(19) United States
(12) Patent Application Publication
(10) Pub. No.: US 2005/0255676 A1
(43) Pub. Date: Nov. 17, 2005

(54) Configuring a performance state of an integrated circuit die on wafer

(76) Inventors: James R. Emmert, Corvallis, OR (US); Michael A. Rencher, Corvallis, OR (US); Charles Evans, Corvallis, OR (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/847,258

(22) Filed: May 17, 2004

(51) Int. Cl. H01L 21/301

(52) U.S. Cl. 438/462

(57) ABSTRACT

Techniques for configuring a performance state of an integrated circuit die that do not consume input/output pin connections to the integrated circuit die. An integrated circuit die according to the present teachings includes a set of configuration lines. Each configuration line determines a performance characteristic of the integrated circuit die. The integrated circuit die is configured for a performance state while on a wafer by cutting one or more of the configuration lines.

### BACKGROUND

A manufacturing process for an integrated circuit may include forming a set of integrated circuit dies on a wafer, cutting the integrated circuit dies from the wafer, and then packaging each integrated circuit die in a chip package that includes a set of input/output pins.

An integrated circuit die may be capable of functioning in different performance states. For example, an integrated circuit die may include a memory and a processor and the processor may be capable of functioning with different memory storage capacities. In addition, an integrated circuit die may include circuitry that is capable of operating at different clock speeds.

It may be desirable during a manufacturing process to configure the performance states of individual integrated circuit dies on a wafer. Configuring the performance state of an integrated circuit die may be used to adapt the integrated circuit die to particular applications and/or systems, etc. For example, some of the integrated circuit dies on a wafer may be configured for relatively high performance, e.g. high memory capacity and/or clock speed, while other of the integrated circuit dies on the same wafer may be configured for lower performance, e.g. lower memory capacity and/or lower clock speed.

Prior techniques for configuring an integrated circuit die may employ external electrical connections after the integrated circuit die is cut away from a wafer. For example, external voltages may be applied to the input/output pins of a chip package that contains an integrated circuit die. The externally applied voltages on the input/output pins may cause the packaged integrated circuit die to function in different operating states.

Unfortunately, such prior techniques for configuring an integrated circuit may consume the limited number of input/output pins on a chip package that may be used for other purposes and may increase the costs of manufacturing.

### SUMMARY OF THE INVENTION

Techniques are disclosed for configuring a performance state of an integrated circuit die that do not consume input/output pin connections to the integrated circuit die. An integrated circuit die according to the present teachings includes a set of configuration lines. Each configuration line determines a performance characteristic of the integrated circuit die. The integrated circuit die is configured for a performance state while on a wafer by cutting one or more of the configuration lines.

Other features and advantages of the present invention will be apparent from the detailed description that follows.

### BRIEF DESCRIPTION OF THE DRAWINGS

The present invention is described with respect to particular exemplary embodiments thereof and reference is accordingly made to the drawings in which:

FIG. 1 shows an integrated circuit die on a wafer according to the present teachings;

FIG. 2 shows a top view a configuration area of an integrated circuit die;

FIG. 3 shows one method for configuring an integrated circuit die while the integrated circuit die is on a wafer;

FIGS. 4a-4b illustrate circuitry for sensing a logic state of a configuration line;

FIGS. 5-6 show examples of circuitry implemented an integrated circuit die that may be configured using the present techniques;

FIG. 7 shows a method for configuring an integrated circuit die at wafer probe according to the present techniques.

### DETAILED DESCRIPTION

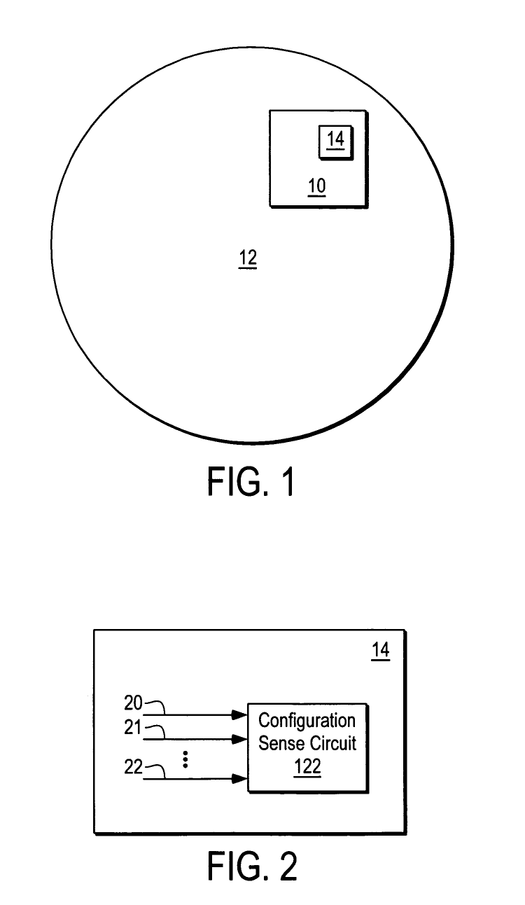

FIG. 1 shows a top view of a wafer 12 according to the present teachings. The wafer 12 includes an integrated circuit die 10. The integrated circuit die 10 may include any type of integrated circuit, e.g. an application-specific integrated circuit (ASIC).

The integrated circuit die 10 includes a configuration area 14. The configuration area 14 includes circuitry that enables configuration of a performance state of the integrated circuit die 10 before the integrated circuit die 10 is cut away from the wafer 12. The configuration area 14 enables the integrated circuit die 10 to be placed into one of a set of possible performance states without using any subsequently formed input/output pin connections to the integrated circuit die 10.

The possible performance states of the integrated circuit die 10 may pertain to any operating characteristic or physical capacity of circuitry formed on the integrated circuit die 10. For example, if the integrated circuit die 10 includes a random access memory then each performance state may pertain to an available storage capacity of the random access memory. In another example, if the integrated circuit die 10 includes a processor or specialized circuitry that may be characterized by timing then each performance state may pertain to a clock speed for that circuit.

The performance state of the integrated circuit die 10 may be configured for a particular application/system. For example, the integrated circuit die 10 may be configured to use the full capacity of its memory and/or run at its highest possible clock speed if it is to be used in a high performance system. Conversely, the integrated circuit die 10 may be configured to use less than the full capacity of its memory and/or run at a lower clock speed if it is to be used in a lower performance system, e.g. a lower cost system, a system that consumes less electrical power, etc.

FIG. 2 shows a top view the configuration area 14 of the integrated circuit die 10. The configuration area 14 includes a set of configuration lines 20-22 and a configuration sense circuit 122. The configuration lines 20-22 each include a portion that is exposed on a top surface of the integrated circuit die 10. Other portions of the configuration lines 20-22 may be routed through lower layers of the integrated circuit die 10. All or portions of the configuration sense circuit 122 may be implemented in lower layers of the integrated circuit die 10.

The exposure of the configuration lines 20-22 at a top surface of the integrated circuit die 10 while the integrated circuit die 10 is on the wafer 12 enables the integrated circuit die 10 to be configured while still on the wafer 12 by cutting one or more of the configuration lines 20-22. For example, the configuration line 20 if cut may indicate a first performance state of the integrated circuit die 10 and if not cut may indicate a second performance state of the integrated circuit die 10. The performance states of the integrated circuit die 10 may be encoded in any manner using the configuration lines 20-22.

The configuration sense circuit 122 senses a performance state of the integrated circuit die 10 by sensing whether any of the configuration lines 20-22 are cut. The configuration lines 20-22 may include any number of configuration lines. For example, one configuration line is capable of indicating two performance states of the integrated circuit die 10. Similarly, two configuration lines may be used to indicated up to four performance states of the integrated circuit die 10 and three configuration lines may be used to indicate up to eight performance states etc.

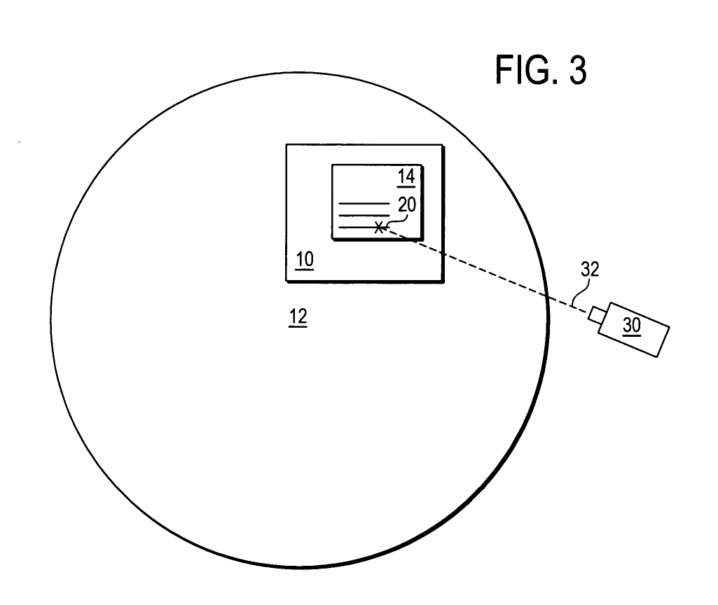

FIG. 3 shows one method for configuring the integrated circuit die 10 while the integrated circuit die 10 is on the wafer 12. In this method, a laser 30 is used to individually cut the configuration lines 20-22 according to the desired performance state. For example, the laser 30 is shown generating a light beam 32 that vaporizes the portion of the configuration line 20 that is exposed on top of the integrated circuit die 10. The laser 30 may be a PHEMTO laser that is also used to cut the integrated circuit die 10 from the wafer 12 during a later step of a manufacturing process.

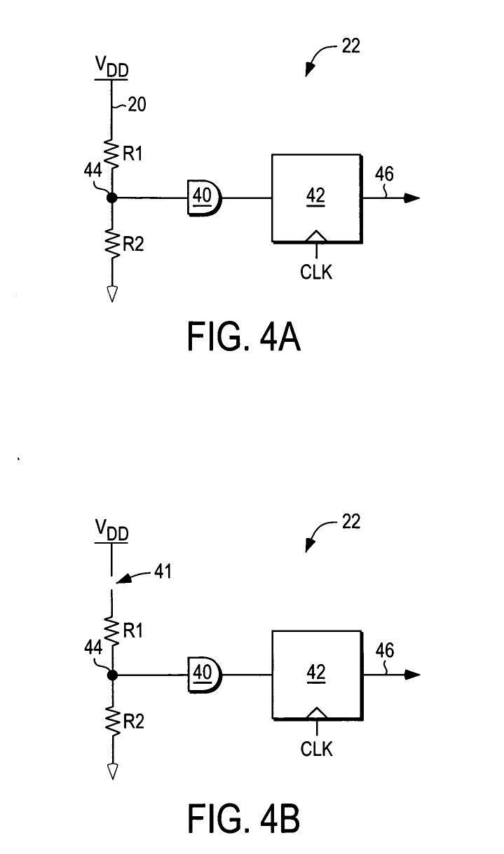

FIGS. 4a-4b illustrate circuitry in the configuration sense circuit 122 for sensing the logic state of the configuration line 20. The configuration sense circuit 122 includes a node 44 coupled to a pull-up resistor R1 and a pull-down resistor R2. The pull-up resistor R1 connects to a voltage supply V_{DD} via the configuration line 20. The pull-down resistor R2 connects to ground.

In FIG. 4a the configuration line 20 is not cut so that the resistor R1 pulls up the voltage at the node 44 to a high voltage level corresponding to a “1” logic state. A gate 40 senses the “1” logic state at the node 44 and sets a flip-flop 42. An output signal 46 of the flip-flop 42 indicates the logic state of the configuration line 20.

In FIG. 4b the configuration line 20 has a cut 41 so that the resistor R1 cannot pull up the voltage at the node 44. Instead, the node 44 is pulled to a low voltage level by the resistor R2. A low voltage level corresponds to a “0” logic state. The gate 40 senses the “0” logic state at the node 44 and resets the flip-flop 42.

In other embodiments, other types of circuits, e.g. multiplexors, buffers, etc., may be used to sense the logic state of the node 44.

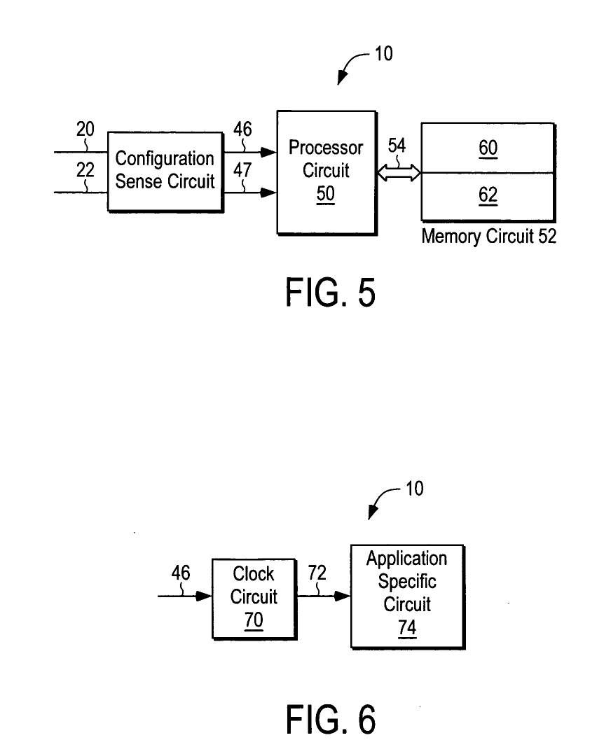

FIG. 5 shows one example of circuitry implemented the integrated circuit die 10 that may be configured while the integrated circuit die 10 is on the wafer 12 using the present techniques. In this example, the integrated circuit die 10 is formed with a processor circuit 50 and a memory circuit 52. The memory circuit 52 includes a pair of sub-areas 60 and 62. The processor circuit 50 accesses the memory circuit 52 via a set of access lines 54. The integrated circuit die 10 may be configured using the present techniques so that the processor circuit 50 uses the sub-area 60 or the sub-area 62 or both sub-areas 60 and 62 or neither sub-area 60-62.

In one embodiment, the configuration line 20 corresponds to the sub-area 60 and the configuration line 21 corresponds to the sub-area 62. The processor circuit 50 determines a configuration of the integrated circuit die 10 using the output signal 46 and an output signal 47 from the configuration sense circuit 122. The output signals 46 and 47 indicate whether the configuration lines 20 and 21, respectively, are cut.

The configuration line 20 may be cut to disable the sub-area 60. Similarly, the configuration line 21 may be cut to disable the sub-area 62. Alternatively, the enabling and/or disabling of the sub-areas 60-62 may be encoded in the combined logic states on the configuration lines 20-21. The processor circuit 50 reads the output signals 46 and 47 to determine whether to use the sub-area 60 or the sub-area 62 or both sub-areas 60 and 62 in its operations.

Thus, the integrated circuit die 10 may be configured in a high performance state by not cutting the configuration line 20-21. A high performance state provides the processor circuit 50 with more memory capacity for performing its tasks. The integrated circuit die 10 may be configured in a lower performance state by cutting the configuration line 20 or 21 or both to disable one or the other or both of the sub-areas 60 and 62. The lower performance states may yield power savings in the integrated circuit die 10.

In other embodiments, the-memory circuit 52 may be arranged into more than two sub-areas and the integrated circuit die 10 may be configured into more possible performance states that are based on the storage capacity of the memory circuit 52.

FIG. 6 shows another example of circuitry implemented the integrated circuit die 10 that may be configured while the integrated circuit die 10 is on the wafer 12 using the present techniques. In this example, the integrated circuit die 10 is formed with a clock circuit 70 that generates a clock signal 72 that controls the timing for an application-specific circuit 74.

In one embodiment, the output signal 46 reflects the logic state of the configuration line 20 which indicates whether the integrated circuit die 10 is configured in a high clock speed state or a lower clock speed state. For example, the configuration line 20 may be cut to configure the integrated circuit die 10 for the lower clock speed. In other embodiments, the integrated circuit die 10 be configured for one of multiple clocks speeds using more of the configuration lines 20-22.

The clock circuit 70 generates the clocks signal 72 at a frequency that is determined by the logic state of the output signal 46. For example, the output signal 46 may be used to control the speed of a phase-lock loop circuit in the clock circuit 70. The frequency of the clock signal 72 may affect the power consumption of the integrated circuit die 10 as well as its operating speed.

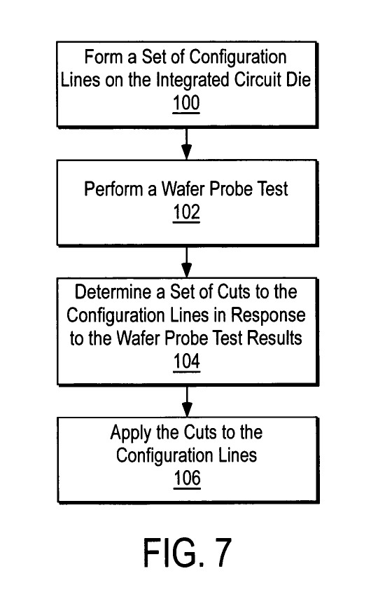

FIG. 7 shows a method for configuring the integrated circuit die 10 at wafer probe according to the present techniques.

At step 100, the configuration lines 20-22 are formed on the integrated circuit die 10 such that a portion of each configuration line 20-22 is exposed at a surface of the integrated circuit die 10. In one embodiment, the configuration lines 20-22 are metal lines that are formed using the same metallization process steps used to form other conductors of the integrated circuit die 10.

At step 102, a wafer probe test is performed on the integrated circuit die 10. Examples of wafer probe tests include memory bit tests and clock speed tests.

At step 104, a set of cuts to the configuration lines 20-22 are determined based on the results of the wafer probe test. For example, if part of a memory on the integrated circuit die 10 failed a bit test at step 102 then a set of cuts is determined that will disable the sub-areas of the memory that failed. In another example, if circuitry on the integrated circuit die 10 failed a high speed test then a set of cuts may be determined that will cause a clock circuit on the integrated circuit die 10 to run at a lower frequency.

At step 106, the cuts, if any, from step 104 are applied to the configuration lines 20-22 while the integrated circuit die 10 is on the wafer 12.

Thereafter, the integrated circuit die 10 is cut from the wafer 12 and the packaged in a known manner.

The foregoing detailed description of the present invention is provided for the purposes of illustration and is not intended to be exhaustive or to limit the invention to the precise embodiment disclosed. Accordingly, the scope of the present invention is defined by the appended claims.

1. A method for configuring a performance state of an integrated circuit die comprising cutting one or more of a set of configuration lines formed on the integrated circuit die while the integrated circuit die is on a wafer such that each configuration line determines a performance characteristic of the integrated circuit die.

2. The method of claim 1, wherein cutting includes applying a laser beam to one or more of the configuration lines.

3. The method of claim 1, wherein cutting includes cutting a configuration line that disables a portion of a memory on the integrated circuit die.

4. The method of claim 1, wherein cutting includes cutting a configuration line that controls a speed of a clock on the integrated circuit die.

5. The method of claim 1, wherein cutting includes cutting one or more of the configuration lines in response to a wafer probe test on the integrated circuit die.

6. The method of claim 5, wherein cutting includes cutting a configuration line that disables a portion of a memory on the integrated circuit die that failed the wafer probe test.

7. The method of claim 5, wherein cutting includes cutting a configuration line that lowers a clock speed of a circuit on the integrated circuit die that failed the wafer probe test.

8. An integrated circuit die on a wafer, comprising:
circuit that is capable of operating at more than one performance state;
configuration area having circuitry that enables the integrated circuit die to be configured into one of the performance states on the wafer.

9. The integrated circuit die of claim 9, wherein the configuration area comprises at least one configuration line and a circuit for sensing a cut in the configuration line.

10. The integrated circuit die of claim 9, wherein the configuration line includes a portion that is exposed on a surface of the integrated circuit die.

11. The integrated circuit die of claim 8, wherein the circuit that is capable of operating at more than one performance state is a memory circuit.

12. The integrated circuit die of claim 11, wherein the configuration area includes a set of configuration lines that determine an available storage capacity of the memory circuit.

13. The integrated circuit die of claim 12, wherein each configuration line is used to disable a corresponding sub-area of the memory circuit.

14. The integrated circuit die of claim 9, wherein the circuit that is capable of operating at more than one performance state is a processor circuit.

15. The integrated circuit die of claim 14, wherein the configuration area includes a set of configuration lines that determine a clock speed for the processor circuit.
